(19) United States
(12) Patent Application Publication
(10) Pub. No.: US 2025/0232942 A1
(43) Pub. Date: Jul. 17, 2025

(54) ION EXTRACTION OPTICS FOR ION PROCESSING SYSTEM

(71) Applicant: Applied Materials, Inc., Santa Clara, CA (US)

(72) Inventors: Costel BILOIU, Rockport, MA (US); David MORRELL, Wakefield, MA (US); Kevin M. DANIELS, Lynnfield, MA (US); Christopher CAMPBELL, Newburyport, MA (US)

(73) Assignee: Applied Materials, Inc., Santa Clara, CA (US)

(21) Appl. No.: 18/415,326

(22) Filed: Jan. 17, 2024

(51) Int. Cl. H01J 37/09; H01J 37/04; H01J 37/08

(52) U.S. Cl. CPC H01J 37/09; H01J 37/045; H01J 37/08; H01J 2237/0435; H01J 2237/0453; H01J 2237/0815

(57) ABSTRACT

An ion extraction optics including an extraction plate defining first, second, and third extraction apertures, the second extraction aperture being located between the first and third extraction apertures, first, second, and third beam blockers located adjacent the first, second, and third extraction apertures, respectively, wherein the first beam blocker and the first extraction aperture define first and second extraction slits, the second beam blocker and the second extraction aperture define third and fourth extraction slits, and the third beam blocker and the third extraction aperture define fifth and sixth extraction slits, wherein a height of the first extraction slit is greater than a height of at least one of the third extraction slit and the fourth extraction slit, and wherein a height of the sixth extraction slit is greater than the height of at least one of the third extraction slit and the fourth extraction slit.

### FIELD OF THE DISCLOSURE

Embodiments of the present disclosure relate generally to the field of ion beam processing apparatus, and more particularly to an improved apparatus and system for extracting ion beams from a plasma.

### BACKGROUND OF THE DISCLOSURE

Known apparatus used to treat substrates with ions include beamline ion implanters and plasma immersion ion implantation tools. These approaches are appropriate for implanting ions over a range of energies. In beamline ion implanters, ions are extracted from a source, mass analyzed, and then transported to a substrate surface. In plasma immersion ion implantation apparatus, a substrate is located in the same chamber where the plasma is generated, adjacent to the plasma. The substrate is set at negative potential with respect to the plasma, and ions crossing the plasma sheath in front of the substrate impinge on the substrate at a perpendicular angle if incidence.

Recently, a new processing apparatus facilitating control of extracted ion angular distribution (IAD) has been developed. In this apparatus, ions are extracted from a plasma chamber where the substrate is located proximate the plasma chamber. Ions are extracted through an extraction aperture of special geometry located in an ion extraction optics placed proximate a plasma. To extract an ion beam having controllable and uniform properties, the extraction aperture may be elongated to generate an ion beam having the shape of a ribbon beam when ions are extracted from the plasma. For example, the ribbon beam may have a cross-section having a short dimension as small as a few millimeters, and a long dimension on the order of 10 centimeters to 50 centimeters. By exposing a substrate to the ribbon beam and scanning a substrate with respect to the extraction aperture along a direction parallel to the short dimension, an entirety of a large substrate, such as a 300 mm wafer, may be exposed to the ribbon beam.

In such an apparatus, to expose a substrate to a targeted dose of ions, the substrate may be scanned with respect to the extraction aperture at an appropriate velocity to allow each portion of the substrate to receive the targeted dose, given the ion density of the ribbon beam and the size of the ribbon beam. Throughput of substrate processing may accordingly be limited by the size of the extraction aperture along the short dimension, as well as the plasma density or ion density of a plasma chamber generating the ribbon beam. While in principle the ion beam current of a ribbon beam delivered to a substrate may be increased by increasing parameters such as the power delivered to the plasma, the increase in power may increase plasma density and may consequently result in undesirable changes in properties of the ribbon beam, such as the angle of incidence of ions or the distribution of angles of incidence of the ions. Likewise, while in principle an aperture size along the short dimension of an aperture may be increased, the ability to manipulate and control the geometry of the ribbon beam when the short dimension is increased beyond a few millimeters to a few centimeters may be impractical. Still further, while in principle the number of extraction apertures may be increased to increase the number of ion beams projected onto a substrate, plasma density within a plasma chamber decreases towards the walls of the plasma chamber. Thus, increasing the number of extraction apertures would result in ion beams with inconsistent angles of incidence if the variations in plasma density are unaccounted for.

With respect to these and other considerations, the present disclosure is provided.

### SUMMARY

This Summary is provided to introduce a selection of concepts in a simplified form further described below in the Detailed Description. This Summary is not intended to identify key features or essential features of the claimed subject matter, nor is the summary intended as an aid in determining the scope of the claimed subject matter.

An ion extraction optics for extracting a plurality of ion beams in accordance with an embodiment of the present disclosure may include an extraction plate defining a first extraction aperture, a second extraction aperture, and a third extraction aperture, the second extraction aperture being located between the first extraction aperture and the third extraction aperture, a first beam blocker located adjacent the first extraction aperture, wherein the first beam blocker and the first extraction aperture define a first extraction slit and a second extraction slit, a second beam blocker located adjacent the second extraction aperture, wherein the second beam blocker and the second extraction aperture define a third extraction slit and a fourth extraction slit, and a third beam blocker located adjacent the third extraction aperture, wherein the third beam blocker and the third extraction aperture define a fifth extraction slit and a sixth extraction slit, wherein a height of the first extraction slit is greater than a height of at least one of the third extraction slit and the fourth extraction slit, and wherein a height of the sixth extraction slit is greater than the height of at least one of the third extraction slit and the fourth extraction slit.

A processing apparatus in accordance with an embodiment of the present disclosure may include a plasma chamber adapted to contain a plasma, a process chamber located adjacent the plasma chamber and adapted to contain a substrate for processing, ion extraction optics located between the plasma chamber and the process chamber and adapted to extract a plurality of ion beams from the plasma chamber and to direct the plurality of ion beams into the process chamber, the ion extraction optics including an extraction plate defining a first extraction aperture, a second extraction aperture, and a third extraction aperture, the second extraction aperture being located between the first extraction aperture and the third extraction aperture, a first beam blocker located adjacent the first extraction aperture, wherein the first beam blocker and the first extraction aperture define a first extraction slit and a second extraction slit, a second beam blocker located adjacent the second extraction aperture, wherein the second beam blocker and the second extraction aperture define a third extraction slit and a fourth extraction slit, and a third beam blocker located adjacent the third extraction aperture, wherein the third beam blocker and the third extraction aperture define a fifth extraction slit and a sixth extraction slit, wherein a height of the first extraction slit is greater than a height of at least one of the third extraction slit and the fourth extraction slit, and wherein a height of the sixth extraction slit is greater than the height of at least one of the third extraction slit and the fourth extraction slit.

### BRIEF DESCRIPTION OF THE DRAWINGS

By way of example, various embodiments of the disclosed techniques will now be described, with reference to the accompanying drawings, wherein:

FIG. 1 is a schematic cross-sectional view illustrating a processing apparatus in accordance with an embodiment of the present disclosure;

FIG. 2A is a cross-sectional view illustrating plasma density within the plasma chamber of the apparatus shown in FIG. 1;

FIG. 2B is a graph illustrating projections of plasma density at various locations within the plasma chamber shown in FIG. 2A;

FIGS. 3A and 3B are cross sectional views illustrating portions of hypothetical ion extraction optics having different geometries;

FIG. 4 is a cross-sectional view illustrating an ion extraction optics in accordance with an embodiment of the present disclosure;

FIGS. 5A-C are a series of graphs illustrating properties of ion beams extracted through the ion extraction optics shown in FIG. 4.

### DETAILED DESCRIPTION

The embodiments described herein provide apparatus for achieving high throughput ion processing of a substrate using a ribbon beam. The present embodiments provide a novel ion extraction optics to generate ion beams from a plasma in a manner increasing ion beam current, while preserving ion beam angular distribution characteristics.

As used herein, the term “angle of incidence” may refer to the mean angle of incidence of a group of ions of an ion beam with respect to the normal on the substrate surface. The term “angular spread” may refer to the width of distribution or range of angles of incidence centered around a mean angle, termed for short. In the embodiments disclosed herein, the novel ion extraction optics may increase ion beam current extracted from a plasma in a ribbon beam configuration, while not affecting, or minimally affecting, other ion beam parameters such as angle of incidence or angular spread.

The ion extraction optics of the present disclosure may generally include an extraction plate defining first, second, and third extraction apertures of equal height (where height is measured in a direction parallel to a front surface of the extraction plate). The ion extraction optics may further include first, second, and third beam blockers disposed adjacent the first, second, and third extraction apertures, respectively, where the first, second, and third beam blockers effectively bifurcate the first, second, and third extraction apertures to define respective pairs of extraction slits flanking the first, second, and third beam blockers, including a central pair of extraction slits flanking the second (middle) beam blocker, an intermediate pair of extraction slits located adjacent inner edges of the first and third beam blockers, and an outer pair of extraction slits located adjacent outer edges of the first and third beam blockers. The heights of the beam blockers and the positions of the beam blockers relative to their respective extraction apertures may be varied so that the heights of the extraction slits increase with their distance from the center of the extraction plate as further described below.

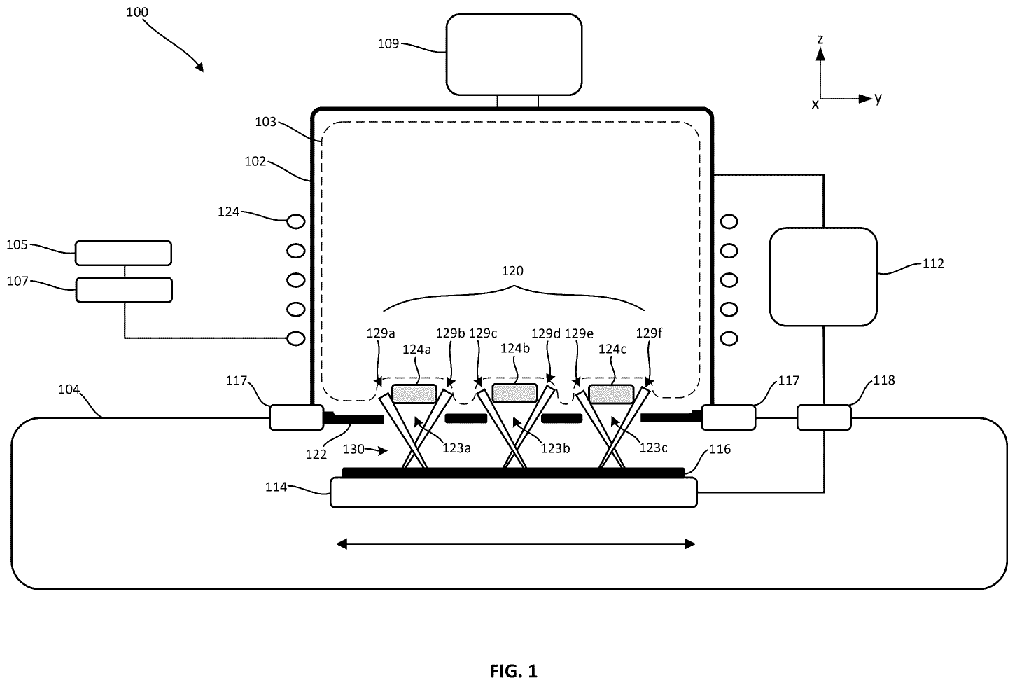

FIG. 1 depicts a processing apparatus 100, in accordance with embodiments of this disclosure. The processing apparatus 100 may include a plasma source comprised of a plasma chamber 102 to generate a plasma 103. The plasma chamber 102 may function as part of a plasma source such as a RF inductively-coupled plasma (ICP) source, a capacitively coupled plasma (CCP) source, a helicon source, an electron cyclotron resonance (ECR) source, an indirectly heated cathode (IHC) source, a glow discharge source, or other plasma sources known to those skilled in the art. In the embodiment illustrated in FIG. 1, the plasma source is an ICP source, where power from an RF generator 105 is coupled into the plasma through an RF matching network 107. The transfer of the RF power from the RF generator 105 to the gas atoms and/or molecules takes places through an antenna 106 and a dielectric window (not shown). A gas manifold 109 may be connected to the plasma chamber 102 through appropriate gas lines and gas inlets. The plasma chamber 102 and/or an adjacent process chamber 104 also may be connected to a vacuum system (not shown), such as a turbo molecular pump backed by a rotary or membrane pump. The plasma chamber 102 may be defined by adjoining chamber walls and may be electrically insulated by insulators 117. The process chamber 104 may include a substrate holder 114 for supporting a substrate 116. The plasma chamber 102 may be biased with respect to the substrate holder 114 and the process chamber 104 using a bias voltage supply 112. For example, the plasma chamber 102 may be held at elevated voltage, such as +1000 V, while the substrate holder 114, substrate 116, and process chamber 104 are grounded. Alternatively, the substrate holder 114 may be held at negative potential, while the plasma chamber 102 is grounded. Electrical connection between the bias voltage supply 112 and the substrate holder 114 may be accomplished through an electrical feedthrough 118. In these scenarios, positive ions may be extracted from the plasma 103 and directed to the substrate 116 at an ion energy proportionate to the difference in voltage between the plasma chamber 102 and the substrate holder 114.

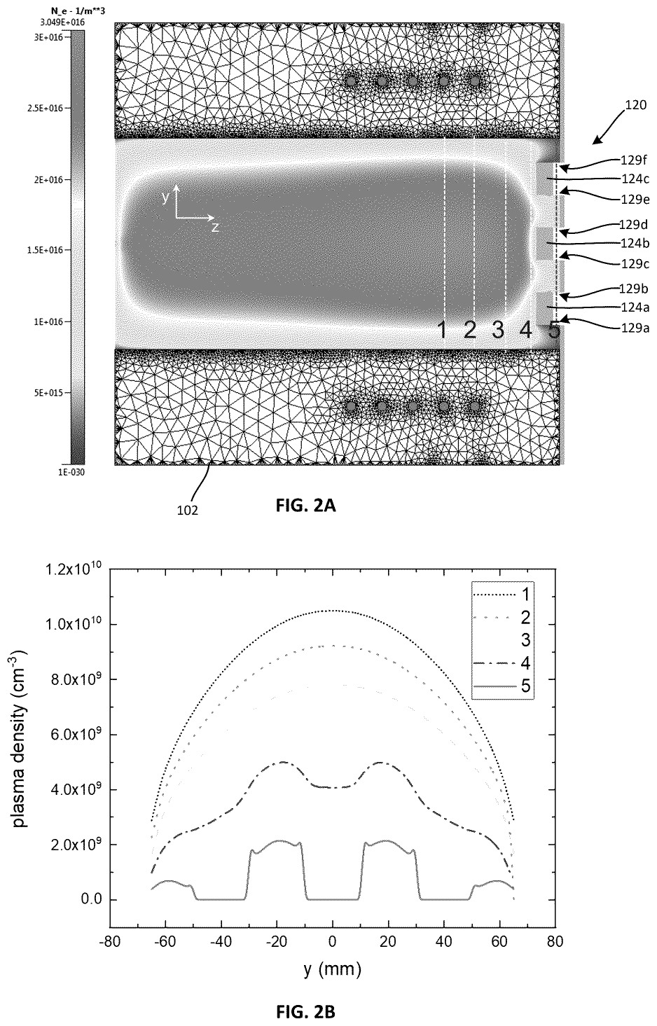

An ion extraction optics 120 may be arranged along a side of plasma chamber 102. In FIG. 1, the ion extraction optics 120 is arranged at the bottom of the plasma chamber 102, extending in a horizontal plane. This orientation is presented for purposes of illustration and is not intended to be limiting. In other views, such as in FIG. 2A, the plasma chamber 102 and the ion extraction optics 120 are oriented (i.e., rotated relative to FIG. 1) such that the ion extraction optics 120 extends in a vertical plane. The present disclosure is not limited in this regard. The ion extraction optics 120 may be disposed between the plasma chamber 102 and the process chamber 104. The ion extraction optics 120 may define a portion of a chamber wall of the plasma chamber 102 or the process chamber 104 or both, in some instances. The ion extraction optics 120 defines apertures through which ions may be extracted as ion beams and directed toward the substrate 116 as further described below.

In various embodiments, the substrate holder 114 may be coupled to a drive (not shown) configured to move the substrate holder 114 along a direction parallel to the y-axis of the illustrated Cartesian coordinate system. In further embodiments, the substrate holder 114 may be movable along a direction parallel to the x-axis, z-axis, or both. This movement provides the processing apparatus 100 with two degrees of freedom, i.e., allows relative position of the substrate vs an extraction aperture to be modified and allows the substrate 116 to be scanned with respect to an aperture so ions may be provided over the entire surface of substrate 116 in some instances. In various embodiments, the substrate holder 114 may be rotatable around the z-axis in small increments, such as increments of 1 degree, so process uniformity can be further improved.

In various embodiments, and as detailed below, the ion extraction optics 120 may include separate components defining a plurality of ion beams. For example, the ion extraction optics 120 may define a plurality of extraction slits, elongated along the x-dimension of the illustrated Cartesian coordinate system (i.e., into the plane of the page in FIG. 1). These extraction slits may define a plurality of ribbon beams, elongated in the x-dimension and having designed properties, such as ion energy, ion current density, designed angle of incidence with respect to the x-axis, and designed angular spread. As detailed below, by providing multiple extraction slits, such as six slits or more, the ion beam current delivered to the substrate 116 may be increased relative to traditional processing apparatus, while not affecting other beam properties.

As further illustrated in FIG. 1, the ion extraction optics 120 may include an extraction plate 122 defining a first extraction aperture 123a, a second extraction aperture 123b, and a third extraction aperture 123c spaced apart along the y-dimension of the illustrated Cartesian coordinate system. The ion extraction optics 120 may further include a first beam blocker 124a, a second beam blocker 124b, and a third beam blocker 124c arranged proximate the first, second, and third extraction apertures 123a-c, respectively. According to various embodiments, in the configuration of FIG. 1, the first, second, and third extraction apertures 123a-c, and the first, second, and third beam blockers 124a-c may define six extraction slits 129a-f. These six extraction slits 129a-f may generate six different ribbon beams, shown as ion beams 130 in FIG. 1. By careful arrangement and sizing of the first beam blocker 124a, the second beam blocker 124b, the third beam blocker 124c, and the three extraction apertures 123a-c defined by the extraction plate 122, increased throughput for processing of the substrate 116 may be obtained, while maintaining uniform (or nearly uniform) ion angular distribution of the ion beams 130 as further described below.

FIG. 2A is a cross sectional view depicting plasma density within the plasma chamber 102 of the processing apparatus 100 during operation. Despite constant gas pressure within the plasma chamber 102, plasma density is greatest toward the center of the plasma chamber 102 and decreases toward the walls of the plasma chamber 102 in both the y and z-dimensions due to inherent ambipolar diffusion of charged particles. Referring to FIG. 2B, a graph illustrating projections of the plasma density along lines 1-5 in FIG. 2A is shown. At line 1, furthest from the ion extraction optics 120, the plasma density has a parabolic profile. Nearer the ion extraction optics 120, at lines 2 and 3, the plasma density decreases but maintains its parabolic profile. At line 4, closer to the ion extraction optics 120 and in the proximity of the first, second, and third beam blockers 124a-c, the plasma density further decreases, and the parabolic profile of the plasma density is perturbed by the presence of the first, second, and third beam blockers 124a-c. Specifically, there are two bumps in the profile which correspond to “plasma pockets” formed between the first beam blocker 124a and the second beam blocker 124b and between the second beam blocker 124b and the third beam blocker 124c, respectively. Finally, at line 5, which extends through the extraction slits 129a-f, the plasma density is further reduced, and at the locations of the outer extraction slits 129a and 129f the plasma density is roughly one third of the plasma density at the central or innermost extraction slits 129b-e.

Ion Angular Distribution (IAD) and ion beam current are driven by a plasma meniscus which defines the boundary between the plasma 103 in a plasma chamber 102 and the vacuum environment of the process chamber 104 (see FIG. 1). Qualitatively, this boundary results from the equilibrium between “plasma pressure” inside the plasma chamber 102 and “electrostatic pressure” outside the plasma chamber 102, in front of an extraction slit. Through continuity and energy conservation laws, the ion flux is related to the Bohm flux at an extraction slit and is thereby related to the bulk plasma density. Accounting only for single ionized ions (Z=1), the Bohm current density at the emitting surface is given by,

$${j}_{B} = 0.61 e {n}_{0} \sqrt{{k}_{B} {T}_{e} / {m}_{i}}$$

where e is the elementary charge, no is the electron density in the bulk of the plasma 103, kB is the Boltzmann constant, and mi is the ion mass. The shape and the location of a plasma meniscus results from the balance between Bohm current density and space-charge limited current density given by the Child-Langmuir law,

$${j}_{C - L} = \frac{4 {ε}_{0}}{9} {( \frac{2 e}{{m}_{i}} )}^{\frac{1}{2}} \frac{{V}_{e}^{\frac{3}{2}}}{{z}^{2}}$$

where ε₀ is the dielectric constant of the vacuum, Vₑ is the extraction voltage, and Z is the gap length between extraction plate 122 and substrate being processed. Thus, a lower plasma density and/or a stronger electrostatic field correspond to a deeper and more concave plasma meniscus, while a higher plasma density and/or a weaker electrostatic field correspond to a more shallow and less concave plasma meniscus. If unaccounted for, this large variation in plasma density across the extraction slits 129a-f will produce slit-to-slit variations in ion beam current and angular distribution. For example, the deeper and more concave plasma meniscus associated with a lower plasma density will produce an ion beam with a greater initial extraction angle, and the shallower and less concave plasma meniscus associated with a higher plasma density will produce an ion beam with a smaller initial extraction angle.

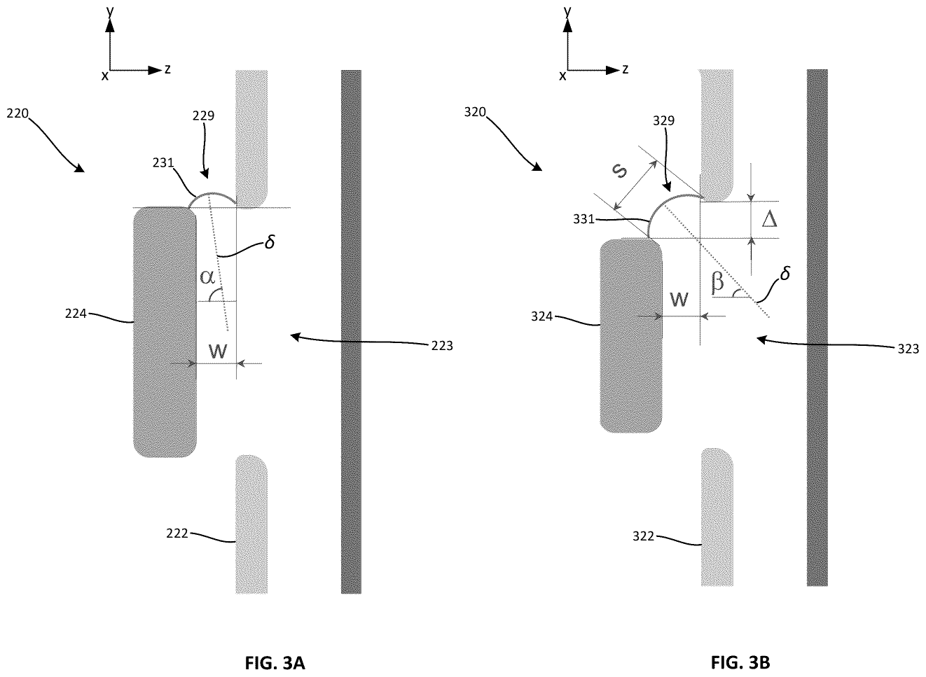

Referring to FIGS. 3A and 3B, cross sectional views illustrating portions of hypothetical ion extraction optics 220 and 320 having two different geometries are shown. In the case of FIG. 3A, the beam blocker 224 is separated from the extraction plate 222 by distance w along the z-dimension of the illustrated Cartesian coordinate system, and the beam blocker 224 has a height measured in the y-dimension of the illustrated Cartesian coordinate system that is equal to a height of the extraction aperture 223 in the extraction plate 222. Thus, there is no separation along the y dimension between the outermost edges of the beam blocker 224 and the edges of the extraction plate 222 defining the extraction aperture 223. Given this geometry, the size of the extraction slit 229 is equal to w, and the plasma meniscus 231 is oriented such that ions are extracted along a direction δ at a very large angle α (referred to hereinafter as “angle of extraction”), almost at grazing incidence (i.e., close to 90° relative to the illustrated z-axis). For the case depicted in FIG. 3B, plasma density, electrostatic field, and the distance w between the beam blocker 324 and the extraction plate 322 are the same as in FIG. 3A. However, unlike the geometry of FIG. 3A, the beam blocker 324 has a height that is less than a height of the extraction aperture 323 in the extraction plate 322, creating a separation A between a top edge of the beam blocker 324 and an edge of the extraction plate 322 defining a top of the extraction aperture 323 (the separation between the bottom edge of the beam blocker 324 and the edge of the extraction plate 322 defining a bottom of the aperture may be equal to, less than, or greater than 4). Given this geometry, the extraction slit 329 has a size S, and the plasma meniscus 331 is oriented such that ions are extracted along a direction δ at an angle of extraction β that is less than the angle of extraction α of the geometry shown in FIG. 3A.

With the above in mind, it will be understood that losses in plasma density toward the walls of a plasma chamber, and the effect of such losses on IAD, may be compensated by varying extraction slit geometry, such as by increasing the height of an extraction slit (where height is measured along the y-dimension of the Cartesian coordinate system illustrated in FIG. 3B). Thus, while weaker plasma density tends to increase the initial extraction angle of an ion beam, increasing the height of the extraction slit through which the ion beam is extracted will have the opposite effect, i.e., it will decrease the initial extraction angle of the ion beam. Furthermore, losses in ion beam current associated with lower plasma density may also be compensated (at least partially) by increasing the height of an extraction slit, since ion beam current increases with the size of the extraction slit as given by the equation,

$${I}_{b e a m} = {j}_{B o h m} {A}_{m e n i s c u s} ≅ {j}_{B o h m} \times 2 R L arcsin \frac{s}{2 R}$$

where R is the radius of the plasma meniscus, L is the height of the plasma meniscus, and s is the chord of the plasma meniscus.

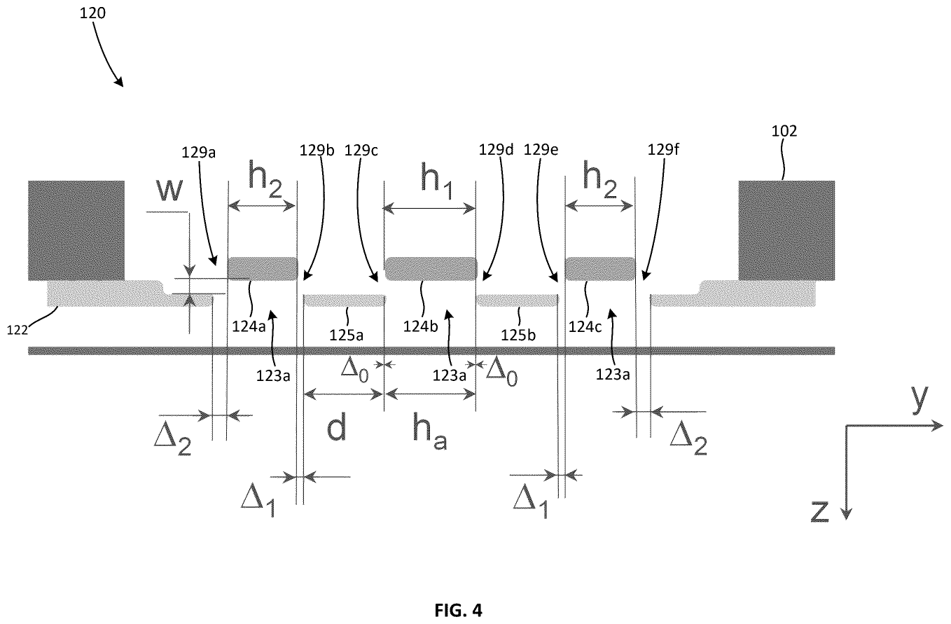

Referring now to FIG. 4, a detailed cross-sectional view illustrating the ion extraction optics 120 of the processing apparatus 100 (see FIG. 1) of the present disclosure is shown. As described above, the ion extraction optics 120 may include an extraction plate 122 defining a first extraction aperture 123a, a second extraction aperture 123b, and a third extraction aperture 123c spaced apart along the y-dimension of the illustrated Cartesian coordinate system and separated by adjacent portions of the extraction plate, hereinafter referred to as “the first spacer 125a” and “the second spacer 125b”. The ion extraction optics 120 may further include a first beam blocker 124a, a second beam blocker 124b, and a third beam blocker 124c arranged proximate the first, second, and third extraction apertures 123a-c, respectively. The first, second, and third beam blockers 124a-c may effectively bifurcate the first, second, and third extraction apertures 123a-c to define a first extraction slit 129a, a second extraction slit 129b, a third extraction slit 129c, a fourth extraction slit 129d, a fifth extraction slit 129e, and a sixth extraction slit 129f. The six extraction slits 129a-f may be grouped into three pairs defined by proximity to the center of the extraction plate 122 along the y dimension: central extraction slits 129c, 129d, intermediate extraction slits 129b, 129e, and outer extraction slits 129a, 129f.

As shown in FIG. 4, the first, second, and third extraction apertures 123a-c may be equal in height (where height is measured along the y dimension), wherein such height is denoted by hₐ, and the first and second spacers 125a, 125b may be equal in height, wherein such height is denoted by d. The first, second, and third beam blockers 124a-c may be spaced apart from the extraction plate by width w (where width is measured along the z dimension). The central, second beam blocker 124b may have a height h₁ substantially equal to the height hₐ of the central, second extraction aperture 123b, with the central extraction slits 129c, 129d on either side of the second beam blocker 124b having equal heights denoted by Δ₀ (where, in some embodiments, Δ₀ may be equal to zero or near zero). The outer, first and third beam blockers 124a, 124c may have equal heights h₂ less than the heights hₐ of the outer, first and third extraction apertures 123a, 123c, with the intermediate extraction slits 129b, 129e having equal heights denoted by Δ₁, where Δ₁ is greater than Δ₀. The outer extraction slits 129a, 129f may have equal heights denoted by 42, where 42 is greater than Δ₁. In various non-limiting examples, 41 may be in a range of 1 millimeter to 3 millimeters, and 42 may be in a range of 3 millimeters to 5 millimeters. The present disclosure is not limited in this regard. Thus, the extraction slits 129a-f may increase in height as they get further away from the center of the extraction plate 122. As described above, this variation in the heights of the extraction slits 129a-f may compensate for diminishing plasma density toward the walls of the plasma chamber 102 which, if left unaccounted for, would result in undesirable variations in IAD from slit to slit and diminished total ion beam current. For example, the heights of the extraction slits 129a-f may be designed or tuned to account for variations in plasma density as identified in the analysis shown in FIG. 2B. In various embodiments, the heights of the extraction slits 129a-f may be designed or tuned to produce ion beams having nearly identical angles of extraction. For example, the intermediate extraction slits 129b, 129e and the outer extraction slits 129a, 129f may have heights adapted to extract ions beams at angles less than 1 degree different than ion beams extracted from the central extraction slits 129c, 129d.

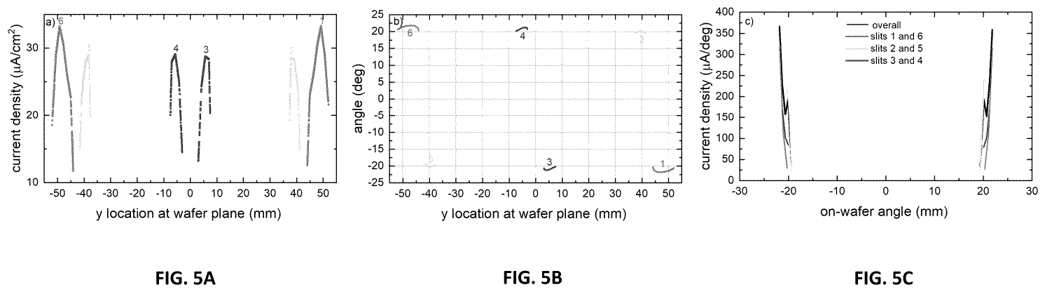

Referring to FIGS. 5A-C, and with continued reference to FIG. 4, a series of graphs depicting properties of ion beams extracted through the extraction slits 129a-f of the ion extraction optics 120 are shown, wherein reference numerals “1” and “6” in the graphs denote ion beams extracted through the outer extraction slits 129a, 129f, reference numerals “2” and “5” in the graphs denote ion beams extracted through the intermediate extraction slits 129b, 129e, and reference numerals “3” and “4” in the graphs denote ion beams extracted through the central extraction slits 129c, 129d. As shown in FIG. 5A, the ion beams 2-5 have nearly identical ion beam currents, with ion beams 1 and 6 having higher ion beam currents (i.e., ion beam current is the integral of current density, and is thus depicted as the area beneath the curves in FIG. 5A). FIG. 5B depicts emissivity curves for the ion beams 1-6, illustrating that ion beams 1-6 are only slightly divergent. FIG. 5C illustrates that the ion beams 1-6 have nearly identical IADs.

Those of skill in the art will appreciate the numerous benefits provided by the above-described configurations. For example, the ion extraction optics 120 of the present disclosure provides significantly increased ion beam current relative to traditional extraction optics. Furthermore, the ion extraction optics 120 facilitate production of a plurality of ion beams with substantially consistent IADs.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, while the present disclosure has been described herein in the context of a particular implementation in a particular environment for a particular purpose, those of ordinary skill in the art will recognize its usefulness is not limited thereto. Embodiments of the present disclosure may be beneficially implemented in any number of environments for any number of purposes. Accordingly, the claims set forth below shall be construed in view of the full breadth and spirit of the present disclosure as described herein.

1. An ion extraction optics for extracting a plurality of ion beams, comprising:
an extraction plate defining a first extraction aperture, a second extraction aperture, and a third extraction aperture, the second extraction aperture being located between the first extraction aperture and the third extraction aperture;
a first beam blocker located adjacent the first extraction aperture, wherein the first beam blocker and the first extraction aperture define a first extraction slit and a second extraction slit;
a second beam blocker located adjacent the second extraction aperture, wherein the second beam blocker and the second extraction aperture define a third extraction slit and a fourth extraction slit; and
a third beam blocker located adjacent the third extraction aperture, wherein the third beam blocker and the third extraction aperture define a fifth extraction slit and a sixth extraction slit;
wherein a height of the first extraction slit is greater than a height of at least one of the third extraction slit and the fourth extraction slit, and wherein a height of the sixth extraction slit is greater than the height of at least one of the third extraction slit and the fourth extraction slit.

2. The ion extraction optics of claim 1, wherein the first extraction slit is further away from the second extraction aperture than the second extraction slit, the sixth extraction slit is further away from the second extraction aperture than the fifth extraction slit, the second extraction slit and the fifth extraction slit have a first height, the first extraction aperture and the sixth extraction aperture have a second height, wherein the second height is greater than the first height.

3. The ion extraction optics of claim 2, wherein the first height is in a range of 1 millimeter to 3 millimeters and wherein the second height is in a range of 3 millimeters to 5 millimeters.

4. The ion extraction optics of claim 2, wherein the first extraction slit is configured to produce an ion beam at a first angle of extraction, the second extraction slit is configured to produce an ion beam at a second angle of extraction, and the third extraction slit is configured to produce an ion beam at a third angle of extraction, wherein the first angle of extraction and the second angle of extraction are less than 1 degree different from the third angle of extraction.

5. The ion extraction optics of claim 4, wherein the fourth extraction slit is configured to produce an ion beam at a fourth angle of extraction, the fifth extraction slit is configured to produce an ion beam at a fifth angle of extraction, and the sixth extraction slit is configured to produce an ion beam at a sixth angle of extraction, wherein the fifth angle of extraction and the sixth angle of extraction are less than 1 degree different from the fourth angle of extraction.

6. The ion extraction optics of claim 1, wherein the third extraction slit and the fourth extraction slit have a height of zero.

7. The ion extraction optics of claim 1, wherein the second beam blocker has a first height and wherein the first beam blocker and the third beam blocker have a second height, wherein the first height is greater than the second height.

8. The ion extraction optics of claim 1, wherein the first extraction aperture, the second extraction aperture, and the third extraction aperture are equal in height.

9. The ion extraction optics of claim 1, wherein the first extraction slit, the second extraction slit, the third extraction slit, the fourth extraction slit, the fifth extraction slit, and the sixth extraction slit are equal in width.

10. The ion extraction optics of claim 1, wherein a height of the second beam blocker is equal to a height of the second extraction aperture, and wherein heights of the first beam blocker and the third beam blocker are less than heights of the first extraction aperture and the third extraction aperture, respectively.

11. A processing apparatus comprising:
a plasma chamber adapted to contain a plasma;
a process chamber located adjacent the plasma chamber and adapted to contain a substrate for processing;
ion extraction optics located between the plasma chamber and the process chamber and adapted to extract a plurality of ion beams from the plasma chamber and to direct the plurality of ion beams into the process chamber, the ion extraction optics comprising:
an extraction plate defining a first extraction aperture, a second extraction aperture, and a third extraction aperture, the second extraction aperture being located between the first extraction aperture and the third extraction aperture;
a first beam blocker located adjacent the first extraction aperture, wherein the first beam blocker and the first extraction aperture define a first extraction slit and a second extraction slit;
a second beam blocker located adjacent the second extraction aperture, wherein the second beam blocker and the second extraction aperture define a third extraction slit and a fourth extraction slit; and
a third beam blocker located adjacent the third extraction aperture, wherein the third beam blocker and the third extraction aperture define a fifth extraction slit and a sixth extraction slit;
wherein a height of the first extraction slit is greater than a height of at least one of the third extraction slit and the fourth extraction slit, and wherein a height of the sixth extraction slit is greater than the height of at least one of the third extraction slit and the fourth extraction slit.

12. The processing apparatus of claim 11, wherein the first extraction slit is further away from the second extraction aperture than the second extraction slit, the sixth extraction slit is further away from the second extraction aperture than the fifth extraction slit, the second extraction slit and the fifth extraction slit have a first height, the first extraction aperture and the sixth extraction aperture have a second height, wherein the second height is greater than the first height.

13. The processing apparatus of claim 12, wherein the first height is in a range of 1 millimeter to 3 millimeters and wherein the second height is in a range of 3 millimeters to 5 millimeters.

14. The processing apparatus of claim 12, wherein the first extraction slit is configured to produce an ion beam at a first angle of extraction, the second extraction slit is configured to produce an ion beam at a second angle of extraction, and the third extraction slit is configured to produce an ion beam at a third angle of extraction, wherein the first angle of extraction and the second angle of extraction are less than 1 degree different from the third angle of extraction.

15. The processing apparatus of claim 14, wherein the fourth extraction slit is configured to produce an ion beam at a fourth angle of extraction, the fifth extraction slit is configured to produce an ion beam at a fifth angle of extraction, and the sixth extraction slit is configured to produce an ion beam at a sixth angle of extraction, wherein the fifth angle of extraction and the sixth angle of extraction are less than 1 degree different from the fourth angle of extraction.

16. The processing apparatus of claim 11, wherein the third extraction slit and the fourth extraction slit have a height of zero.

17. The processing apparatus of claim 11, wherein the second beam blocker has a first height and wherein the first beam blocker and the third beam blocker have a second height, wherein the first height is greater than the second height.

18. The processing apparatus of claim 11, wherein the first extraction aperture, the second extraction aperture, and the third extraction aperture are equal in height.

19. The processing apparatus of claim 11, wherein the first extraction slit, the second extraction slit, the third extraction slit, the fourth extraction slit, the fifth extraction slit, and the sixth extraction slit are equal in width.

20. The processing apparatus of claim 11, wherein a height of the second beam blocker is equal to a height of the second extraction aperture, and wherein heights of the first beam blocker and the third beam blocker are less than heights of the first extraction aperture and the third extraction aperture, respectively.
